(19) United States
(12) Patent Application Publication
(10) Pub. No.: US 2022/0351901 A1
(43) Pub. Date: Nov. 3, 2022

(54) Low Cost In-Package Power Inductor

(71) Applicant: NXP B.V., Eindhoven (NL)

(72) Inventor: Trevor Mark Newlin, Mesa, AZ (US)

(73) Assignee: NXP B.V., Eindhoven (NL)

(21) Appl. No.: 17/245,284

(22) Filed: Apr. 30, 2021

(51) Int. Cl. H01F 41/10; H01F 41/04; H01F 27/28; H01L 23/64

(52) U.S. Cl. CPC H01F 41/10; H01F 41/046; H01F 27/2804; H01F 27/2828; H01L 23/645

(57) ABSTRACT

A method and apparatus are described for fabricating a microchip structure (60A) which includes a first chip (41) that is affixed to a lead frame strip (11-18) having a plurality of lead frame pads (11-16) in a circuit mounting area (19) and a planar lead frame inductor coil (17) that is laterally displaced from the circuit mounting area (19), where molded body (61) encapsulates the first chip (41), lead frame pads (11-16) and planar lead frame inductor coil (17).

### BACKGROUND OF THE INVENTION

### Field of the Invention

The present invention is directed in general to the field of packaged integrated circuit devices. In one aspect, the present invention relates to the integration of inductive electrical elements into semiconductor packages.

### Description of the Related Art

The electronics industry constantly strives to increase the function and performance of electronic devices while decreasing their cost. One approach to meet this goal is to integrate passive elements, such as inductors or capacitors and active semiconductor components, into the same package. However, the size and space requirements for conventional inductive elements (especially for looping coil-type inductors) make them unsuitable for integration within the semiconductor packaging when the inductive element is significantly larger than the integrated circuit (IC) which drives it. For example, existing semiconductor packages have mounted an inductor element side-by-side with an integrated circuit on a printed circuit board or a substrate, but the form factor of large inductor elements increases the overall size of the semiconductor package to a degree that is unsuitable for cost and/or size constraints of commercial applications. Another drawback arises when using pre-formed inductors having relatively large form factor and poor thermal performance since their integration with the IC can further increase the overall form factor of the semiconductor package and degrade the thermal performance. There have been attempts to address these problems by incorporating an inductor element into the printed circuit board so that the inductor is located above or below the integrated circuit, but in addition to the increased package size requirements to account for the inductor form factor, the inductor can create large magnetic fields which interfere with the operation of the integrated circuit. Further limitations and disadvantages of conventional packaging processes and technologies will become apparent to one of skill in the art after reviewing the remainder of the present application with reference to the drawings and detailed description which follow.

### BRIEF DESCRIPTION OF THE DRAWINGS

The present invention may be understood, and its numerous objects, features and advantages obtained, when the following detailed description is considered in conjunction with the following drawings.

FIG. 1 depicts a side view and isometric top view of a lead frame having a lateral planar inductor coil in accordance with selected embodiments of the present disclosure.

FIG. 2 illustrates processing subsequent to FIG. 1 with a side view and isometric top view after forming a filler layer around the lead frame in accordance with selected embodiments of the present disclosure.

FIG. 3 illustrates processing subsequent to FIG. 2 with a side view and isometric top view after forming a copper pillar pattern to match the lead frame in accordance with selected embodiments of the present disclosure.

FIG. 4 illustrates processing subsequent to FIG. 3 with a side view and isometric top view after attaching a flip chip integrated circuit die to the lead frame in accordance with selected embodiments of the present disclosure.

FIG. 5 illustrates processing subsequent to FIG. 4 with a side view and isometric top view after applying a ferrite coating to cover at least the lateral planar inductor coil in accordance with selected embodiments of the present disclosure.

FIG. 6 illustrates processing subsequent to FIG. 5 with a side view and isometric top view after encapsulation of the flip chip integrated circuit die, lead frame, and ferrite coating with a mold compound.

FIG. 7 illustrates an example flow chart depicting a process of fabricating and encapsulating a lead frame assembly with lateral planar inductor coil and integrated circuit with a mold compound package in accordance with selected embodiments of the present disclosure.

### DETAILED DESCRIPTION

A method and apparatus are described for fabricating integrated circuit die in lead frame packages (e.g., QFN packages) which include an integrated, low cost, in-package power inductor. In selected embodiments, the power inductor is formed integrally with a QFN lead frame as a planar inductor coil that is laterally displaced from a plurality of lead frame pads (a.k.a. lands or pins) which are positioned for electrical attachment to a flip-chip (FC) integrated circuit die. In such FC-QFN embodiments, the lateral planar inductor coil may be a low resistance inductor formed as part of the lead frame with a first inductor terminal end electrically connected at a first, upper surface of the QFN package to the FC IC die, and a second, external inductor terminal end electrically connected at a second, lower surface of the QFN package. In particular, the lead frame may have external pads, lands or pin conductors on multiple sides of the QFN package, and may include a patterned, planar inductor coil on at least one side of the QFN package that is laterally displaced from the integrated circuit (IC) mounting area on the QFN package. By laterally displacing the location of the patterned, planar lead frame inductor coil from the IC mounting area, the inductor area may be covered with a ferrite coating to shape or reduce the magnetic field generated by the planar inductor coil so as to improve inductance and/or reduce interference with the operation of the integrated circuit. With the formation of a laterally displaced, planar lead frame inductor coil that is adjacent to an integrated circuit, such as a power integrated circuit, the top of each integrated circuit die and inductor coil may be covered with a molding compound using any desired packaging scheme, including but not limited to QFN (Quad Flat No leads), Plastic Quad-Flat No lead (PQFN), SOIC (Small-Outline Integrated Circuit), QFP (Quad Flat Package), BGA (Ball Grid Array), or LGA (Land Grid Array) packaging.

Various illustrative embodiments of the present invention will now be described in detail with reference to the accompanying figures. While various details are set forth in the following description, it will be appreciated that the present invention may be practiced without these specific details, and that numerous implementation-specific decisions may be made to the invention described herein to achieve the device designer's specific goals, such as compliance with process technology or design-related constraints, which will vary from one implementation to another. While such a development effort might be complex and time-consuming, it would nevertheless be a routine undertaking for those of ordinary skill in the art having the benefit of this disclosure. For example, selected aspects are depicted with reference to simplified cross sectional and perspective drawings of a lead frame strip and associated packaging without including every device feature or geometry in order to avoid limiting or obscuring the present invention. Such descriptions and representations are used by those skilled in the art to describe and convey the substance of their work to others skilled in the art. In addition, certain elements in the figures are illustrated for simplicity and clarity and have not necessarily been drawn to scale. Further, reference numerals have been repeated among the drawings to represent corresponding or analogous elements.

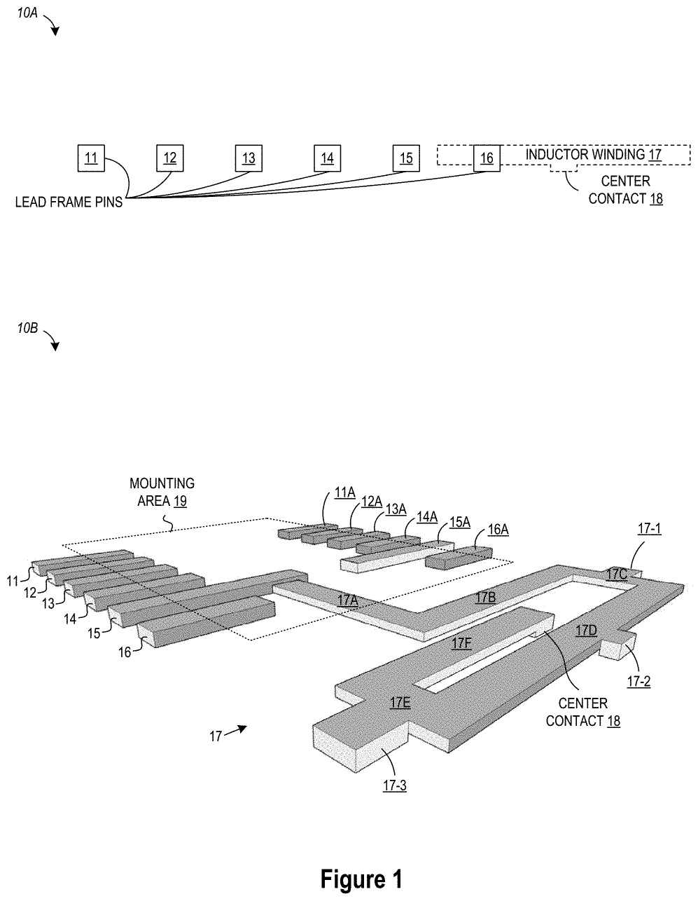

To illustrate an example fabrication sequence for packaging one or more inductive electrical elements with one or more integrated circuit devices into semiconductor packages, reference is now made to FIG. 1 which provides a side view 10A and isometric top view 10B of a lead frame having a plurality of lead frame pins 11-16, 11A-16A and a lateral planar inductor coil 17-18 that is suitable for use in conjunction with selected embodiments of the present invention. As will be appreciated, the lead frame 11-18 may be produced by stamping or etching a portion of a metal (e.g., copper or copper alloy) strip with a predetermined pattern of lead frame features, including lead frame pins 11-16, 11A-16A (which are positioned in an IC mounting area 19 for alignment with electrical contacts in a flip-chip integrated circuit) and a lateral planar inductor coil 17A-F (which is positioned to be laterally displaced from the IC mounting area 19). Though the depicted arrangement of lead frame pins 11-16, 11A-16A is positioned to extend from two sides of a QFN package, it will be appreciated that the lead frame pins may extend to additional or fewer sides of the final QFN package.

As depicted, the lateral planar inductor coil 17 includes a first terminal segment 17A which extends into the IC mounting area 19 for alignment with electrical contacts in a flip-chip integrated circuit. The lateral planar inductor coil 17 also includes inductor coil segments 17B-17F which may be symmetrically arrayed in a planar pattern outside of the mounting area 19 to form an inductor coil with one or more turns. At a second terminal segment 17F, the lateral planar inductor coil 17 is connected to a center contact 18 which may be formed as an unetched portion of the second terminal segment 17F, thereby providing a connection to the center of the inductor 17. The lateral planar inductor coil 17 may also include structural support tabs 17-1, 17-2, 17-3 which are positioned to support the inductor coil segments 17C-17E and which may be formed as unetched portions of the lateral planar inductor coil 17. Formed with one or two windings, the lateral planar inductor coil 17 provides relatively small inductance values (e.g., 100-200 nH) with low resistance losses that are be suitable for high switching speed applications. Indeed, based on the lead-frame design and the permeability of the coating, the inductance value of the lateral planar inductor coil 17 may be between 100-200 nH.

In selected embodiments, the lateral planar lead frame features 11-18 may be connected to a dam bar (not shown) to provide structural integrity during the fabrication process, though portions of the dam bar are later removed (i.e., trimmed) from lead frame 11-18 during device processing to physically separate and electrically isolate adjacent electrical contacts 11-18, as shown. In other embodiments, the lateral planar lead frame features 11-18 may also include other features, such as die attach flags, interior electrical contacts, exterior electrical contacts, etc. At this point or subsequently in the fabrication process, the lead frame surfaces that will be exposed to the external environment may be plated or covered with a lead finish (e.g., with NiPdAu).

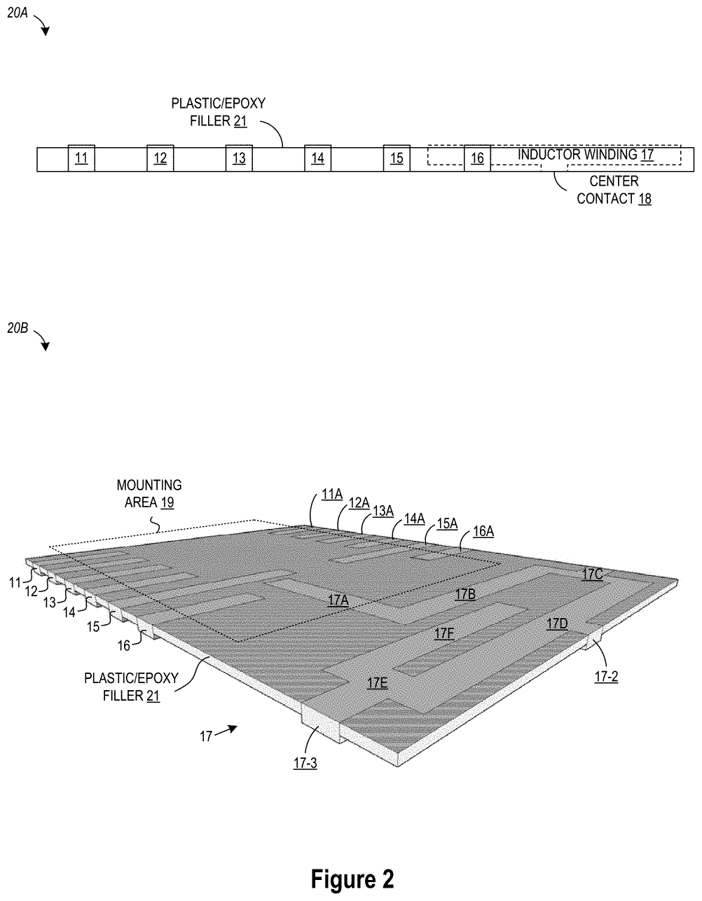

Turning now to FIG. 2, there is illustrated processing subsequent to FIG. 1 with a side view 20A and isometric top view 20B after forming a filler layer 21 around the lead frame 11-18 to form a QFN package substrate in accordance with selected embodiments of the present disclosure. In selected embodiments, the filler layer/QFN package substrate 21 may be formed between the lead frame features 11-18 with a plastic filler or epoxy compound using any suitable molding or fabrication technique. As formed, the filter layer 21 leaves exposed the lead frame features 11-16, 11A-16A, 17A-E on a first, upper surface of the QFN package substrate where the flip-chip integrated circuit die will be mounted. In addition, the filter layer 21 is formed to leave exposed the unetched or non-recessed lead frame features 11-16, 11A-16A, 17-1, 17-2, 17-3 on a second, lower surface of the QFN package substrate where external electrical connections will be made to an underlying printed circuit board (not shown). As illustrated, the shape of the filler layer 21 extends beyond the IC mounting area 19 to a side that will support the inductor 17B-17F in a laterally displaced position with respect to the IC mounting area 19. The lateral displacement of the planar inductor lead frame features 17B-17F with respect to the IC mounting area 19 may also provide space to integrate the boot cap and some input decoupling (now shown).

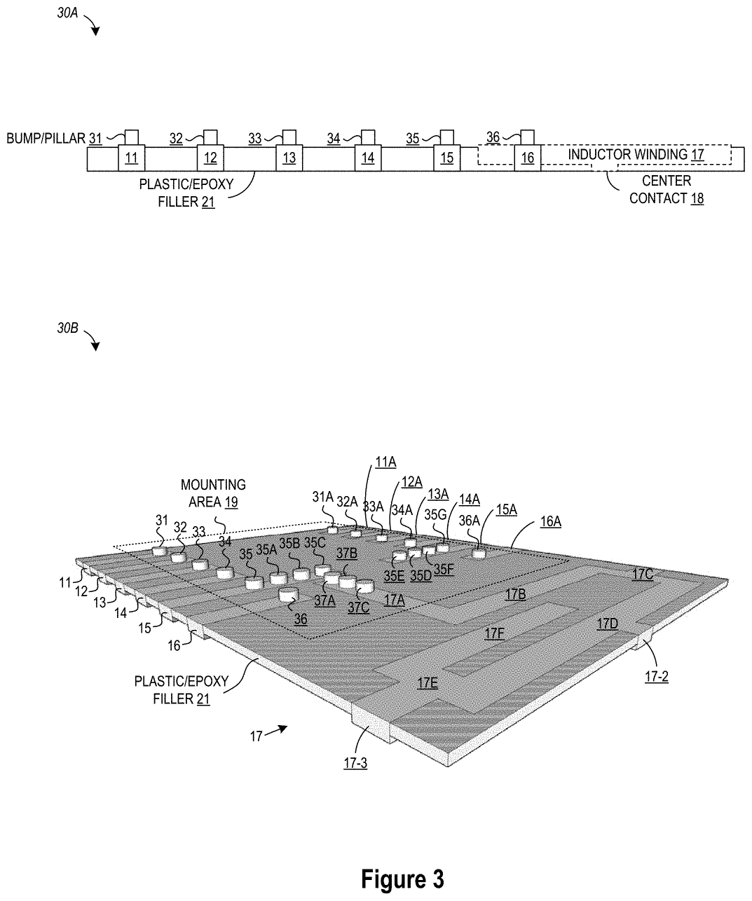

Turning now to FIG. 3, there is illustrated processing subsequent to FIG. 2 with a side view 30A and isometric top view 30B after forming a forming a pattern of conductive bumps or pillars 31-37 in the mounting area 19 in accordance with selected embodiments of the present disclosure. In selected embodiments, the pattern of conductive pillars 31-37 is positioned to match or overlap with the plurality of lead frame pins 11-16, 11A-16A and the first inductor terminal segment 17A. Using any suitable conductive bonding or solder technique, the conductive pillars 31-35, 35A-C, and 36 are affixed to the lead frame pins 11-16 on one side of the QFN package. In addition, the conductive pillars 31A-34A, 35E-G, and 36A are affixed to the lead frame pins 11A-16A on a second side of the QFN package. Finally, the conductive pillars 37A-37C are affixed to the first inductor terminal segment 17A of the lead frame. As will be appreciated, the conductive pillars 31-37 may be formed using any suitable conductive material that can be patterned or otherwise precisely formed on the corresponding lead frame features 11-16, 11A-16A, 17A to make electrical connection to the subsequently mounted flip-chip integrated circuit.

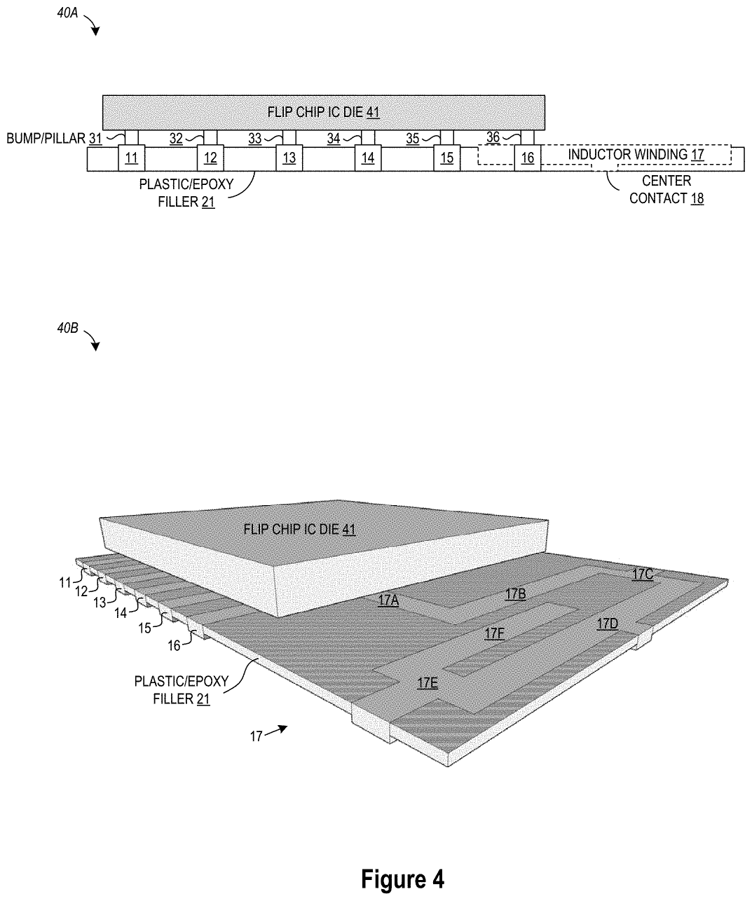

Turning now to FIG. 4, there is illustrated processing subsequent to FIG. 3 with a side view 40A and isometric top view 40B after attaching a flip-chip integrated circuit die 41 to the pattern of conductive bumps or pillars 31-37 and lead frame features 11-16, 11A-16A, 17A in accordance with selected embodiments of the present disclosure. While any desired integrated circuit die 41 may be attached, in selected embodiments, the integrated circuit die 41 is a power IC die having a plurality of electrical contacts formed on the underside (not shown) which are positioned to match or overlap with the conductive pillars 31-37 positioned in the IC mounting area 19. As will be appreciated, the flip-chip IC die 41 may be attached and electrically connected to the conductive pillars 31-37 using any suitable die attach technique for making electrical connection between the flip-chip integrated circuit and lead frame features 11-16, 11A-16A, 17A. As illustrated, the flip-chip integrated circuit die 41 is positioned on the QFN package filler layer 21 so that it does not extend over the inductor lead frame features 17B-17F, thereby reducing interference to the operation of the flip-chip IC die 41 from magnetic fields running in the lateral planar inductor coil 17A-F.

In addition, there may be embodiments where a planar lead frame inductor coil is located within the mounting area 19 (not shown) and below the IC die 41, in which case one or more protective structures may be added to reduce the effect of the underlying inductor's magnetic fields on the operation of the IC die 41. In such embodiments, holes will need to be formed in the underlying printed circuit board (not shown) in order to connect to the underlying planar lead frame inductor coil.

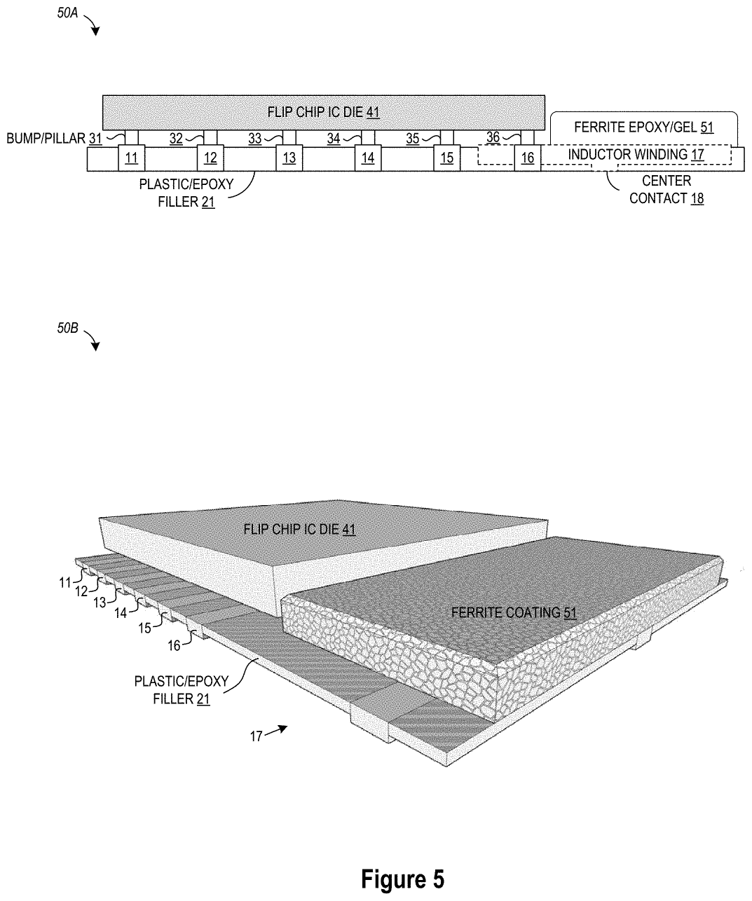

Turning now to FIG. 5, there is illustrated processing subsequent to FIG. 4 with a side view 50A and isometric top view 50B after applying or injecting a ferrite coating or paste 51 to cover at least the lateral lead frame planar inductor coil 17 in accordance with selected embodiments of the present disclosure. In selected embodiments, the ferrite coating 51 is positioned over the lateral inductor area by depositing ferrite loaded epoxy or gel over the lateral inductor lead frame features 17A-17F outside of the IC mounting area 19. In other embodiments, the ferrite coating 51 may be formed over the flip-chip IC die 41 and the lateral lead frame inductor features 17A-17F. The function of the ferrite coating 51 is to shape or reduce the magnetic field so as not to affect the IC die 41, thereby allowing higher chip functionality. The ferrite coating 51 also serves to improve and increase the inductance of the lateral lead frame planar inductor coil 17. However, the ferrite coating 51 is optionally not formed in other embodiments where the field shaping and/or inductance enhancement is not needed.

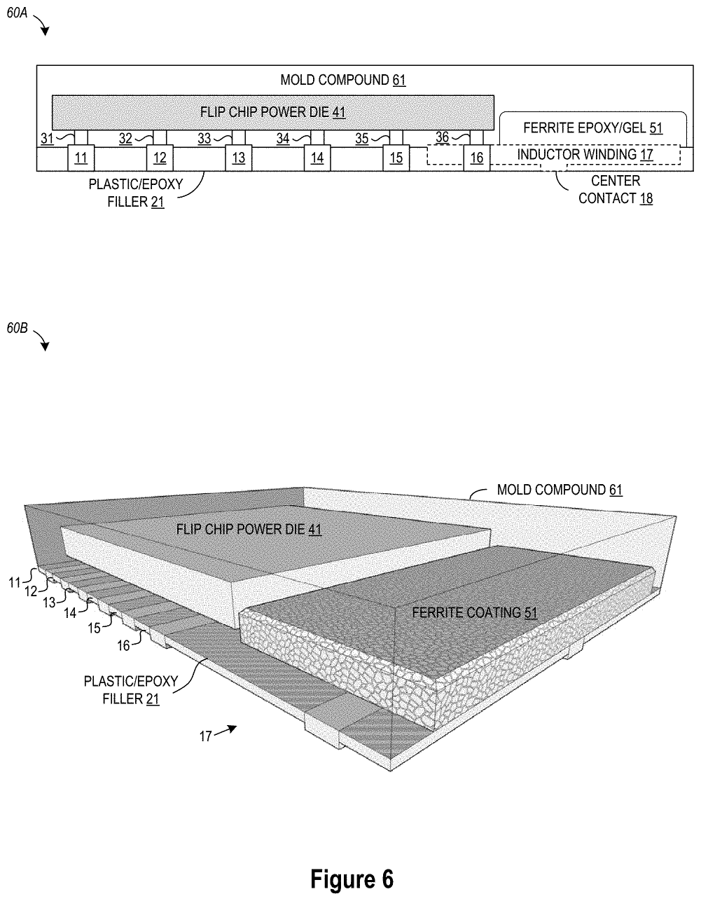

Turning now to FIG. 6, there is illustrated processing subsequent to FIG. 5 with a side view 60A and isometric top view 60B after encapsulation of the flip-chip integrated circuit die 41, lead frame 11-18, and ferrite coating 51 with a mold compound 61 to form a semiconductor package in accordance with selected embodiments of the present disclosure. In particular, after bonding the integrated circuit die 41 to the lead frame features 11-16, 11A-16A, 17A and (optionally) forming the ferrite coating 51 over the lateral inductor lead frame features 17A-17F, the assembled circuit package may be encapsulated with a molded body 61 to form a semiconductor package. As will be appreciated, the molded body 61 may be formed using an over-molded or transfer molded composite plastic, such as fused silica. As formed, the top of the IC die 41, the lateral lead frame inductor features 17A-17F, and the ferrite coating 51 will be covered with the molding compound 61 and thereby protected from the environment.

In embodiments where the flip-chip integrated circuit die 41 is a low input/output voltage power stage with high frequency switching speeds (e.g., 3-4 MHz), the laterally-displaced planar inductor coil 17A-F does add to the size of the resulting semiconductor package. However, this arrangement does provide a low resistance inductor that generates sufficient inductance (e.g., 100-200 nanohenries or nH) for a 5-10 Å power stage to provide 1-2 amps on a 10 amp output. As a result, the semiconductor package having a space requirement of 5×7 mm² can more than double the power density over conventional manufacturing solutions. For example, it is estimated that the extra cost of incorporating a laterally-displaced planar inductor coil into the semiconductor package would be 2-3 cents per semiconductor package, and with the added manufacturing margin of 5 cents, this would save around 5 cents as compared to a cheap high current inductor that would cost approximately 10 cents.

Another advantage of integrating the lateral lead frame inductor coil 17A-F is that the size of the underlying printed circuit board (PCB) can be reduced as compared to conventional PCB-based inductor (planar) with a ferrite clamshell over the top and bottom layer of the PCB. In particular, even though the printed circuit board will have a custom footprint to allow connection to the center contact 18 of the lateral planar inductor coil 17, any size increase for center contact connection is reduced since there is no external inductor (or associated connectivity) required. However, the area of the printed circuit board under the lateral planar inductor coil 17 should not have other conductive layers to avoid eddy current loss.

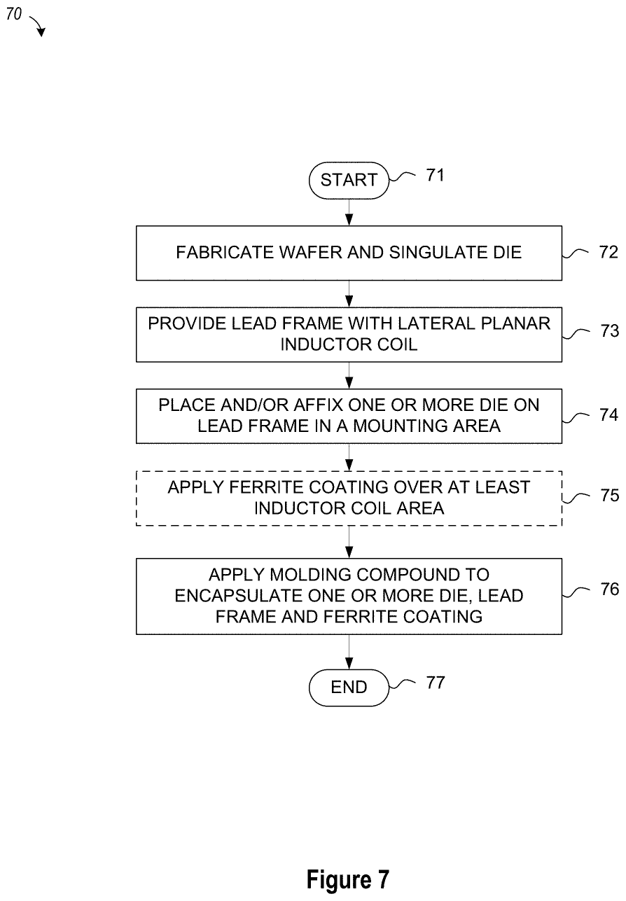

Turning now to FIG. 7, there is illustrated an example flow chart 70 depicting a process 71-77 of fabricating and encapsulating a lead frame assembly with lateral planar inductor coil and integrated circuit with a mold compound package in accordance with selected embodiments of the present disclosure. After the process begins (step 71), a wafer is fabricated using any desired semiconductor fabrication sequence and then singulated to form an individual die (step 72), such as a flip-chip die. At a minimum, the wafer is formed to include a plurality of integrated circuit die, typically having identical circuitry. At this stage, additional wafers may be fabricated with different integrated circuit die (e.g., power circuit die). At this step, each wafer is singulated into one or more integrated circuit dice.

At step 73, a lead frame is provided with a lateral planar inductor coil. As will be appreciated, lead frame strips can be obtained from lead frame suppliers with the plurality of lead frame pins or contact leads grouped in an IC mounting area, and with a planar inductor coil that is laterally displaced from a plurality of lead frame pins/contact pins. Alternatively, the lead frame may be produced by stamping or etching a portion of a metal strip (e.g., copper or copper alloy) with a predetermined pattern of lead frame features. As will be appreciated, the lead frame strips can be selectively plated with nickel palladium or other suitable material, while the intended saw streets are formed with exposed metal material, such as copper. Each provided lead frame may include recessed areas for the coiled portions of planar inductor, and may include non-recessed areas for connection to the underlying printed circuit board and/or to the subsequently attached integrated circuit die. At step 73, each lead frame may be packaged with a plastic or epoxy filler to form a QFN package substrate.

At step 74, one or more integrated circuit die is placed or affixed to the lead frame structure using any desired die attach technology which connects leads from the one or more integrated circuit die to corresponding lead frame pins/contact pins. In selected embodiments where the integrated circuit die is a flip-chip integrated circuit die, leads from the flip-chip IC die are bonded or attached to a pattern of conductive bumps or pillars formed on the lead frame pins or contact leads grouped in the IC mounting area, thereby electrically connecting the flip-chip integrated circuit die to the plurality of lead frame pins/contact pins and to at least one end of the lateral planar lead frame inductor coil.

At step 75, a ferrite coating is applied over at least the lateral planar lead frame inductor coil area. In selected embodiments, the ferrite coating is injected as a ferrite paste over the inductor winding. In other embodiments, the ferrite coating is applied over the entire assembly, including the inductor winding and affixed integrated circuit die. Using commercially available mixtures of ferrite and filler epoxy, the ferrite coating controls the amount to inductance generated by the lateral planar lead frame inductor coil and also reduced the electromagnetic interaction between the lateral planar lead frame inductor coil and the integrated circuit die or other circuit board elements. Optionally, the ferrite coating step 75 may be omitted, as indicated with the dashed lines.

At step 76, a molding compound is applied to encapsulate the mounted integrated circuit die, the lead frame (including lateral planar lead frame inductor), and the ferrite coating. The molding process may use any suitable molding or encapsulation packaging process, such as a QFN molding process to encapsulate the integrated circuit die, lead frame and ferrite coating while retaining exposed die flags and leads which physically and electrically connect integrated circuit die to printed circuit boards. At step 77, the fabrication process ends.

By now, it should be appreciated that there has been provided herein a microchip structure and associated method for fabrication. The disclosed microchip structure includes a lead frame strip having a plurality of lead frame pads in a circuit mounting area and a planar lead frame inductor coil that is laterally displaced from the circuit mounting area. In selected embodiments, the lead frame strip comprises a Quad Flat No lead (QFN) lead frame. In other embodiments, the planar lead frame inductor coil includes a first lead frame inductor terminal end which extends into the circuit mounting area, and a second lead frame inductor terminal end which extends to a bottom surface of the microchip structure. In other embodiments, the planar lead frame inductor coil has a total inductance value in a range of 100-200 nanohenries. In other embodiments, the total inductance value of the planar lead frame inductor coil is in the range of 50-500 nanohenries. The microchip structure also includes a first chip affixed to the lead frame strip in the circuit mounting area, where the first chip includes a plurality of contact leads that are electrically connected to the plurality of lead frame pads and to at least a first terminal end of the planar lead frame inductor coil. In selected embodiments, the first chip is a flip-chip power integrated circuit die that is affixed to the lead frame strip by a patterned plurality of conductive bumps or pillars. In addition, the microchip structure also includes a molded body formed over lead frame strip to encapsulate the first chip and the planar lead frame inductor coil, leaving exposed the plurality of lead frame pads on the bottom of the microchip structure. In selected embodiments, the microchip structure includes a ferrite coating covering the planar lead frame inductor coil. In selected embodiments, the overall footprint of the microchip structure is approximately 5 mm by 7 mm.

In another form, there is provided a packaged microchip structure and associated method for packaging same. In the disclosed methodology, providing a lead frame strip is provided which includes (a) a plurality of lead frame pads and a first inductor coil terminal pad in a circuit mounting area, and (b) a planar lead frame inductor coil that is laterally displaced from the circuit mounting area. In selected embodiments, the lead frame strip is provided as a Quad Flat No lead (QFN) lead frame. In other embodiments, the planar lead frame inductor coil includes a planar inductor formed in a plane of the lead frame strip with one or more turns; a first lead frame inductor terminal end connecting a first end of the planar inductor to the first inductor coil terminal pad in the circuit mounting area; and a second lead frame inductor terminal end connecting a second end of the planar inductor to a bottom surface of the microchip structure. In yet other embodiments, the lead frame strip is provided by etching or stamping a metal strip with a predetermined pattern of lead frame features to form the planar lead frame inductor coil with the plurality of lead frame pads and first inductor coil terminal pad. The disclosed methodology also includes affixing a first chip to the lead frame strip in the circuit mounting area to electrically connect a plurality of contact leads on the first chip to the plurality of contact leads and the first inductor coil terminal pad. In selected embodiments, the first chip is a flip-chip power integrated circuit die that is affixed to the lead frame strip by forming a patterned plurality of conductive bumps or pillars. In addition, the disclosed methodology includes forming a molded body over the lead frame strip to encapsulate the first chip and the planar lead frame inductor coil. In selected embodiments, the planar lead frame inductor coil may be covered with a ferrite coating before forming the molded body. In selected embodiments, the overall footprint of the lead frame strip is approximately 5 mm by 7 mm, and the planar lead frame inductor coil has a total inductance value in a range of 100-200 nanohenries.

In yet another form, there is provided a semiconductor power device package and method for making same. As disclosed, the semiconductor power device package includes a lead frame formed in a package substrate layer to define a plurality of lead frame pads, a first inductor coil terminal pad, a second inductor coil terminal pad, and a planar lead frame inductor coil connected between the first and second inductor coil terminal pads and laterally displaced from the plurality of lead frame pads, where the planar lead frame inductor coil and plurality of lead frame pads are exposed on a first surface of the package substrate layer. The semiconductor power device package also includes a patterned plurality of conductive bumps or pillars formed on the first surface of the package substrate layer in contact with the plurality of lead frame pads and a first inductor coil terminal pad. In addition, the semiconductor power device package includes flip-chip integrated circuit power die comprising a plurality of contact leads attached to the patterned plurality of conductive bumps or pillars to make directly electrical connection to the plurality of lead frame pads and the first inductor coil terminal pad. The semiconductor power device package also includes a molded body formed over the first surface of the package substrate layer to encapsulate the flip-chip integrated circuit power die and the planar lead frame inductor coil. In selected embodiments, the semiconductor power device package also includes a ferrite coating covering the planar lead frame inductor coil on the first surface of the package substrate layer. In selected embodiments of the semiconductor power device package, the planar lead frame inductor coil has a total inductance value in a range of 50-500 nanohenries, and the semiconductor power device package has an overall footprint of approximately 5 mm by 7 mm.

Although the described exemplary embodiments disclosed herein are directed to various packaged semiconductor devices and methods for making same, the present invention is not necessarily limited to the example embodiments which illustrate inventive aspects of the present invention that are applicable to a wide variety of device packaging processes and/or devices. While the disclosed packaged semiconductor devices may be implemented with one or more power integrated circuits formed on a lead frame assembly, the fabrication process described herein is not limited to any particular integrated circuit arrangement or lead frame connector assembly, but is also applicable to any one of numerous package devices that include an encapsulating material formed to protect an integrated circuit die affixed or connected to a lead frame which includes a lateral planar inductor coil. In addition, the lateral planar lead frame inductor coil may be incorporated in any desired packaging scheme, including but not limited to QFN (Quad Flat No leads), SOIC (Small-Outline Integrated Circuit), QFP (Quad Flat Package), BGA (Ball Grid Array), or LGA (Land Grid Array) packaging. In addition, the packaging process may be applied simultaneously to multiple lead frames which are affixed to a process carrier so that multiple IC die are affixed and connected to respective IC mounting areas leaving exposed multiple lateral planar lead frame inductor coil areas for subsequent processing. Thus, the particular embodiments disclosed above are illustrative only and should not be taken as limitations upon the present invention, as the invention may be modified and practiced in different but equivalent manners apparent to those skilled in the art having the benefit of the teachings herein. For example, the methodology of the present invention may be applied using materials other than expressly set forth herein. In addition, the process steps may be performed in an alternative order than what is presented. Accordingly, the foregoing description is not intended to limit the invention to the particular form set forth, but on the contrary, is intended to cover such alternatives, modifications and equivalents as may be included within the spirit and scope of the invention as defined by the appended claims so that those skilled in the art should understand that they can make various changes, substitutions and alterations without departing from the spirit and scope of the invention in its broadest form.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature or element of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

What is claimed is:

1. A microchip structure, comprising:
a lead frame strip comprising a plurality of lead frame pads in a circuit mounting area and a planar lead frame inductor coil that is laterally displaced from the circuit mounting area;
a first chip comprising a plurality of contact leads, where the first chip is affixed to the lead frame strip in the circuit mounting area and where the plurality of contact leads are electrically connected to the plurality of lead frame pads and to at least a first terminal end of the planar lead frame inductor coil; and
a molded body formed over lead frame strip to encapsulate the first chip and the planar lead frame inductor coil.

2. The microchip structure of claim 1, where the lead frame strip comprises a Quad Flat No lead (QFN) lead frame.

3. The microchip structure of claim 1, where the first chip comprises a flip-chip power integrated circuit die that is affixed to the lead frame strip by a patterned plurality of conductive bumps or pillars.

4. The microchip structure of claim 1, further comprising a ferrite coating covering the planar lead frame inductor coil.

5. The microchip structure of claim 1, where the planar lead frame inductor coil comprises a first lead frame inductor terminal end which extends into the circuit mounting area, and a second lead frame inductor terminal end which extends to a bottom surface of the microchip structure.

6. The microchip structure of claim 1, where the planar lead frame inductor coil has a total inductance value in a range of 100-200 nanohenries.

7. The microchip structure of claim 1, where the planar lead frame inductor coil has a total inductance value in a range of 50-500 nanohenries.

8. The microchip structure of claim 1, where the microchip structure has an overall footprint of approximately 5 mm by 7 mm.

9. A method of fabricating a microchip structure comprising:
providing a lead frame strip comprising:
a plurality of lead frame pads and a first inductor coil terminal pad in a circuit mounting area, and
a planar lead frame inductor coil that is laterally displaced from the circuit mounting area;
affixing a first chip to the lead frame strip in the circuit mounting area to electrically connect a plurality of contact leads on the first chip to the plurality of contact leads and the first inductor coil terminal pad; and
forming a molded body over the lead frame strip to encapsulate the first chip and the planar lead frame inductor coil.

10. The method of claim 9, where providing the lead frame strip comprises providing a Quad Flat No lead (QFN) lead frame.

11. The method of claim 9, where affixing the first chip comprises affixing a flip-chip power integrated circuit die to the lead frame strip by forming a patterned plurality of conductive bumps or pillars.

12. The method of claim 9, further comprising covering the planar lead frame inductor coil with a ferrite coating before forming the molded body.

13. The method of claim 9, where providing the planar lead frame inductor coil comprises:
a planar inductor formed in a plane of the lead frame strip with one or more turns;
a first lead frame inductor terminal end connecting a first end of the planar inductor to the first inductor coil terminal pad in the circuit mounting area; and
a second lead frame inductor terminal end connecting a second end of the planar inductor to a bottom surface of the microchip structure.

14. The method of claim 9, where the planar lead frame inductor coil has a total inductance value in a range of 100-200 nanohenries.

15. The method of claim 9, where providing the lead frame strip comprises providing a lead frame strip having an overall footprint of approximately 5 mm by 7 mm.

16. The method of claim 9, where providing the lead frame strip comprises etching or stamping a metal strip with a predetermined pattern of lead frame features to form the planar lead frame inductor coil with the plurality of lead frame pads and first inductor coil terminal pad.

17. A semiconductor power device package, comprising:
a lead frame formed in a package substrate layer to define a plurality of lead frame pads, a first inductor coil terminal pad, a second inductor coil terminal pad, and a planar lead frame inductor coil connected between the first and second inductor coil terminal pads and laterally displaced from the plurality of lead frame pads, where the planar lead frame inductor coil and plurality of lead frame pads are exposed on a first surface of the package substrate layer;
a patterned plurality of conductive bumps or pillars formed on the first surface of the package substrate layer in contact with the plurality of lead frame pads and a first inductor coil terminal pad;
a flip-chip integrated circuit power die comprising a plurality of contact leads attached to the patterned plurality of conductive bumps or pillars to make directly electrical connection to the plurality of lead frame pads and the first inductor coil terminal pad; and
a molded body formed over the first surface of the package substrate layer to encapsulate the flip-chip integrated circuit power die and the planar lead frame inductor coil.

18. The semiconductor power device package of claim 17, further comprising a ferrite coating covering the planar lead frame inductor coil on the first surface of the package substrate layer.

19. The semiconductor power device package of claim 17, where the planar lead frame inductor coil has a total inductance value in a range of 50-500 nanohenries.

20. The semiconductor power device package of claim 17, where the semiconductor power device package has an overall footprint of approximately 5 mm by 7 mm.
